(19) United States
(12) Patent Application Publication
(10) Pub. No.: US 2008/0024139 A1
(43) Pub. Date: Jan. 31, 2008

(54) Device and a Method for Testing At Least One Conductive Joint Forming an Electrical Connection Between an Electrical Component and a Printed Circuit

(75) Inventors: Rocco Iacovella, Vitry Sur Seine (FR); Gerard-Marie Martin, Paris (FR); Laurent Bathellier, Arcueil (FR); Laurent Dutrieux, Montreuil (FR); Philippe Prieur, Charenton Le Pont (FR)

Correspondence Address: OLIFF & BERRIDGE, PLC, P.O. BOX 320850, ALEXANDRIA, VA, 22320-4850, US

(73) Assignee: Valeo Electronique ET SYstemes De Liaison

(21) Appl. No.: 11/632,852

(22) PCT Filed: Jul. 18, 2005
(86) PCT No.: PCT/FR05/01833

§ 371 Date: May 15, 2007

(30) Foreign Application Priority Data
Jul. 23, 2004 (FR) 0408193

(51) Int. Cl. G01R 31/04; G01R 31/28

(52) U.S. Cl. 324/522; 324/535

(57) ABSTRACT

The test device comprises a support forming a printed circuit (12) and an electrical component (14) having at least one conductive termination (16) connected to the printed circuit (12) by the conductive joint (18). The device also comprises detector means (20) carried by the support (12) for detecting an electrical interruption of a circuit under test (22) including the conductive joint (18), and storage means (44) carried by the support (12) for storing the successive times of interruptions.

The present invention relates to a device and a circuit for testing at least one conductive joint forming an electrical connection between an electrical component and a printed circuit.

The term “electrical component” is used below to cover any component commonly referred to as being electrical or electronic.

The manufacture of an electronic card usually requires an electrical component to be assembled electrically and mechanically on a printed circuit via at least one conductive joint forming an electrical and mechanical connection between the electrical component and the printed circuit.

Conductive joints can be made by various assembly techniques, in particular by soldering (with added solder), autogenous welding, contact under pressure, or forced engagement.

Usually, prior to making use of any particular assembly technique for mass-producing electronic cards, it is desired to evaluate the reliability of the technique. For this purpose, proposals have been made to test the conductive joints obtained by some particular assembly technique in application of a protocol that is generally adapted to the intended purpose of the electronic component, for example an electronic card for a motor vehicle.

In order to test a particular conductive joint, a test device is already known in the state of the art that comprises a support forming a printed circuit, and an electrical component having at least one conductive termination connected to the printed circuit by the conductive joint.

The device is generally intended solely for the purpose of testing the conductive joint and it is not designed to implement or test any particular function of the electrical component.

The test device is placed in a test enclosure in order to be subjected to predetermined thermal and mechanical stresses. The test may provide for a series of cycles. By way of example the series may comprise 250 cycles of one hour each.

During testing, the device is connected to means external to the enclosure that comprise an electrical power supply for the test device and means forming a tester in order to detect an electrical interruption in at least one circuit under test. The circuit under test conventionally comprises a run or “daisy chain” made up of conductive joints for testing that are interconnected in series. The tester is located remotely from the test enclosure, so that the enclosure does not disturb the operation of the tester.

The test device generally includes a large number of conductive joints for testing, i.e. a plurality of runs of conductive joints for testing, so it is necessary to provide a large number of connections (usually of the order of several tens) between the test device and the tester, i.e. between the inside and the outside of the enclosure. It is therefore possible to test only a few devices at a time.

To remedy that drawback, proposals have been made in the state of the art, and in particular in US 2004/0036466, for a test device in which the support carries detector means for detecting an electrical interruption in a circuit under test, the circuit under test conventionally including a run made up of conductive joints for testing that are interconnected in series.

The detector means described in that document comprise an electronic bistable associated with each run and controlling an indicator light that is designed to light up whenever an interruption is detected in the run. Where appropriate, it is proposed that successive lighting up of the light carried by the printed circuit can be recorded by means of a video camera.

Because the means for detecting electrical interruptions are on board the printed circuit, it is possible to receive and test a relatively large number of devices simultaneously in the enclosure.

Nevertheless, certain regulations define the reliability of a conductive joint on the basis of a notion of “failure” of the conductive joint. A failure corresponds to a predetermined number of successive interruptions occurring within a predetermined time interval.

Unfortunately, a test device such as that described in US 2004/0036466 does not enable successive interruptions to be detected in a run under test since it detects only the first interruption in the run.

An object of the invention is to propose a test device capable of detecting a failure (in the above-specified meaning) of a conductive joint, and without requiring the test device to be connected during the test to external detector means.

To this end, the invention provides a test device for testing at least one conductive joint forming an electrical connection between an electrical component and a printed circuit, of the type described in US 2004/0036466, and comprising:
a support forming a printed circuit;
an electrical component having at least one conductive termination connected to the printed circuit by the conductive joint; and
detector means carried by the support to detect an electrical interruption of a circuit under test including the conductive joint;

characterized in that it includes storage means carried by the support for storing the successive times of interruptions.

The invention makes it possible to detect a failure, corresponding to a predetermined number of successive interruptions occurring in a predetermined time interval, by making use of the times of the interruptions as stored in the test device. During testing, no connection is required to detector means external to the test enclosure.

The stored interruption times can be recovered at the end of testing and transferred to suitable analyzer means capable of identifying failures as a function of the history of interruptions.

Optionally, the test device may include means carried by the support for determining that the circuit under test has suffered a failure.

It is thus possible to determine in real time whether a failure has occurred.

The test device of the invention may further include one or more of the following characteristics:
the storage means comprise a non-volatile memory;
the test device includes means for measuring at least one environmental parameter associated with the support, and storage means for storing at least one value of said environmental parameter;
the environmental parameter is selected from: a temperature; an acceleration to which the device is subjected; and a degree of humidity;
the test device includes a plurality of electrical component conductive terminations, each connected to the printed circuit via a conductive joint, the circuit under test having a run formed by the conductive joints interconnected in series;
the circuit under test includes a voltage divider bridge including resistive means connected in series with the run;
the resistive means.-comprise two two-terminal resistors connected in parallel;
the means for detecting an interruption comprise means for comparing a voltage output by the bridge with a predetermined threshold;
the detector means comprise logic analysis means provided with the least one input connected to the circuit under test and at least one output connected to the storage means;
the logic analysis means are provided with a plurality of inputs each connected to a corresponding circuit under test;
the logic analysis means are of the field programmable gate array (FPGA) type or of the microcontroller type;
each input of the logic analysis means is duplicated for redundancy purposes;
the storage means include a volatile memory of the logic analysis means;
the logic analysis means include the means for determining failure;
the conductive joint is formed by soldering, autogenous welding, contact under pressure, or forced engagement;
the support includes connection means for connection to an external device, in particular for connecting the storage means to the external device; and
the test device includes means carried by the support for storing operating state parameters of the device in the event of an interruption in the electrical power supply to the device.

The invention also provides a test method for testing at least one conductive joint forming an electrical connection between an electrical component and a printed circuit, the method being of the type in which an electrical interruption is detected in a circuit under test including the conductive joint, the method being characterized in that the interruption is detected by means of a device as defined above.

A test method of the invention may further include one or more of the following characteristics:
the interruption is detected by measuring a steady state parameter of the circuit under test while fed with direct current (DC); and
the interruption is detected by measuring a transient state parameter of the circuit under test while fed in variable manner, preferably with pulses.

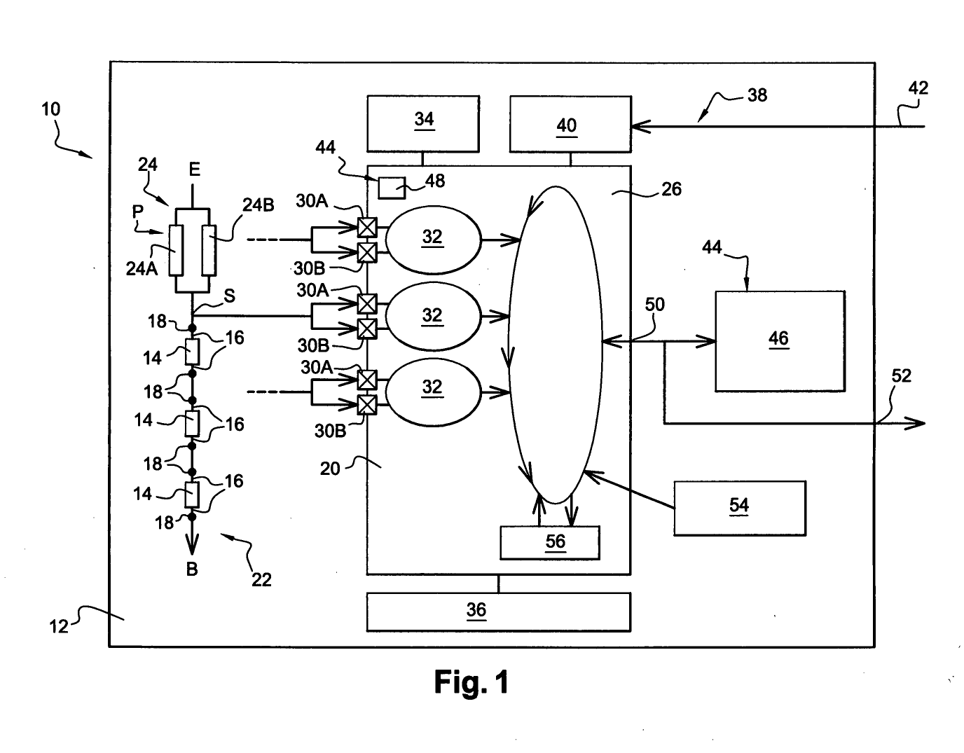

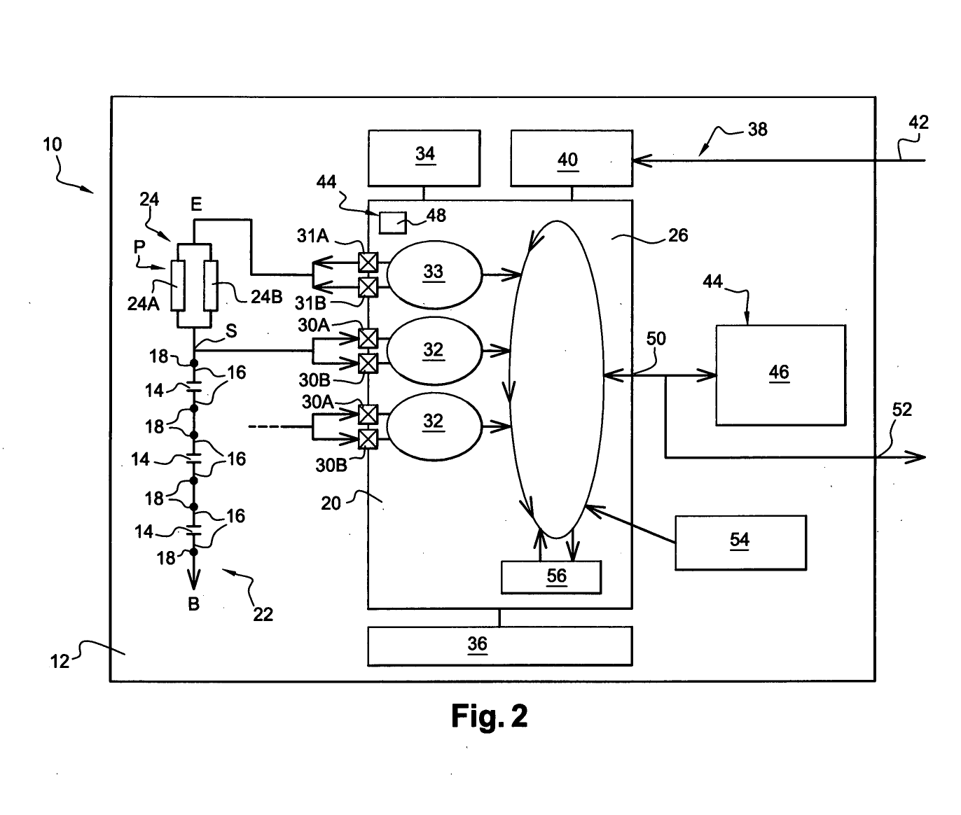

The invention can be better understood on reading the following description given purely by way of example and made with reference to FIGS. 1 and 2 that are diagrams representing first and second embodiments of a test device of the invention.

FIG. 1 shows a test device in a first embodiment of the invention, given overall reference 10.

The device 10 comprises a support forming a printed circuit 12 and electrical components 14, each having at least one conductive termination 16 connected to the printed circuit by a conductive joint 18.

The conductive joints 18 connect the electrical components 14 and the printed circuit 12 not only electrically but also mechanically.

In the example shown, the conductive joints 18 are of the soldered type and the electrical components 14 are passive two-terminal components, e.g. of the resistor type.

In a variant, the electrical components 14 may have more than two terminals. Under such circumstances, the electrical components may be of the surface-mounting type, and in particular of the ball grid array (BGA) type.

The device 10 is for testing the reliability of the conductive joints 18 by detecting unwanted interruptions of said conductive joints 18.

For this purpose, the printed circuit 12 carries detector means 20 for detecting an electrical interruption in a circuit under test 22 that includes at least one conductive joint 18.

In the example described, the device 10 has a plurality of circuits 22 under test, only one of which is shown in FIG. 1.

Each circuit under test 22 preferably includes a run constituted by conductive joints 18 interconnected in series.

The conductive joints 18 in a given run electrically connect the printed circuit 12 to a plurality of conductive terminations 16 of a single electrical component 14 or of a plurality of electrical components 14.

The printed circuit 12 also carries resistive means 24 connected in series with the run of the circuit under test 22 in order to form a voltage divider bridge P.

In the example shown, the resistive means 24 comprise two two-terminal resistors 24A and 24B connected in parallel for redundancy purposes.

The divider bridge P has two terminals B and E between which an input voltage of the bridge is applied.

In the embodiment shown in FIG. 1, the voltage applies between the terminals B and E is a DC voltage.

The divider bridge P also includes a terminal S interposed between the circuit under test 22 and the resistive means 24, constituting a voltage output from the divider bridge P.

The detector means 20 further comprise logic analysis means 26 having inputs 30A, 30B each connected to the output S of the divider bridge P of a corresponding circuit under test 22. Each input 30A, 30B is preferably duplicated for redundancy purposes.

In the example shown, the logic analysis means 26 comprise a circuit of the FPGA type. This type of logic analysis means is particularly well adapted to the relatively large number of inputs required.

In a variant, the logic analysis means 26 could be of the microcontroller type.

The logic analysis means 26 comprise conventional comparator means 32 for comparing the value of the output voltage from the divider bridge P with a predetermined threshold.

It should be observed that different predetermined thresholds may be associated with different inputs.

FIG. 1 also shows conventional oscillator-forming means 34 and conventional initialization memory-forming means 36. These means 34 and 36 are associated in conventional manner with the logic analysis means 26.

The logic analysis means 26 are powered electrically by conventional means 38. These power supply means 38 comprise conventional regulator-forming means 40 associated with the logic analysis means 26 and suitable for being connected to an electrical power supply external to the device 10 via conventional connection means 42.

The test device 10 includes means 44 carried by the printed circuit 12 for storing the successive times of interruptions detected by the means 20.

The storage means 44 preferably comprise a non-volatile memory 46 and a volatile memory 48 integrated in the logic analysis means 26. The logic analysis means 26 include at least one output connected to the non-volatile memory 46.

However, the non-volatile memory 46 is suitable for being connected via conventional connection means 52 to conventional means external to the device 10 for reading said memory.

The logic analysis means 26, the regulator 40, and the non-volatile memory 46 carried by the support 12 form means for storing operating state parameters of the device 10 in the event of the electrical power supply to the device being interrupted.

For this purpose, the regulator 40 is suitable for electrically powering the logic analysis means 26 and the non-volatile memory 46 over a certain length of time after an interruption in the electrical power supply.

The printed circuit 12 preferably also carries means 54 for measuring at least one environmental parameter associated with the printed circuit 12, and means for storing at least one value of the environmental parameter, e.g. constituted by the volatile memory 48.

In the example shown, the environmental parameter measured by the means 54 is a temperature. In a variant, the parameter could be an acceleration to which the test device 10 is subjected, or it could be a degree of humidity.

The operation of the logic analysis means 26 is conventional, the states of the inputs being monitored in application of a cycle driven by a clock 56.

There follows a description of the main aspects associated with the invention of the operation of the test device 10 in the first embodiment.

The test device 10 with a plurality of circuits 22 under test is housed in a conventional test enclosure in which it is subjected to thermal and mechanical stresses in application of a predetermined protocol.

In the test enclosure, the device 10 is connected solely to the electrical power supply means via the connection means 42. The test enclosure may thus contain a relatively large number of test devices 10 of the kind shown in the figure.

It should be observed that during testing, the device 10 is subjected to temperatures that may lie in the range −40° C. to +170° C., for example. The person skilled in the art will therefore select the logic analysis means 26 and the non-volatile memory 46 so that they can withstand such temperatures.

During testing, the logic analysis means 26 monitor the inputs 30A, 30B and identify changes of state therein corresponding to interruptions in the circuits under test 22.

Thus, an interruption is detected by measuring a steady state parameter of the circuit under test 22 that is DC-powered.

The logic analysis means 26 use the non-volatile and/or volatile memories 46 and/or 48 to store the successive times of various interruptions and also indications identifying the circuits under test 22 in which the interruptions occurred.

The logic analysis means 26 also record, at least in the non-volatile memory 46, the environmental parameters measured by the means 54 at the times the interruptions occur in the circuits 22.

At the end of the test, which may last for several days, the interruption times stored in the non-volatile memory 46 can be recovered using the connection means 52 so as to be transferred to conventional analysis means suitable for identifying failures of the various circuits under test 22 as a function of the history of interruptions.

A failure is generally defined as a predetermined number of successive interruptions occurring in a given circuit under test within a predetermined time interval.

The test makes provision for a series of cycles, so in the event of an interruption in the electrical power supply to the device 10, the means 26, 40, 46 store in particular the number of cycles that have already been performed, and the duration remaining for the current cycle.

In a variant, the means for determining failure could be integrated in the logic analysis means 26, the determination means then being carried by the integrated circuit 12. Under such circumstances, failures are determined while the test is in progress, e.g. on the basis of information stored in the volatile memory 48.

FIG. 2 shows a test device constituting a second embodiment of the invention. In FIG. 2, elements that are analogous to those of FIG. 1 are designated by references that are identical.

In this embodiment, the two terminal components 14 are of the capacitive type.

The logic analysis means 26 have an output 31A, 31B that is connected to the terminal E and that is duplicated for redundancy purposes.

The logic analysis means 26 also include means 33 for generating a voltage pulse for application between the terminals E and B of the circuit under test 22.

In this embodiment, an interruption in the circuit under test 22 is detected by measuring a transient condition parameter of the circuit under test 22 that is fed with electricity in variable manner by the logic analysis means 26, preferably with pulses.

The invention is not limited to the embodiments described above.

In particular, the printed circuit 12 may be fitted with indicator lights, each of which can be switched on when an interruption or a failure occurs in a circuit under test 22.

Amongst the advantages of the invention, it should be observed that the device 10 makes it possible to test conductive joints connecting the integrated circuit to components of a very wide variety of types, whether passive or active.

1-21. (canceled)

22. A test device for testing at least one conducive joint forming an electrical connection between an electrical component and a printed circuit, the device being of the type comprising:
a support forming a printed circuit;
an electrical component having at least one conductive termination connected to the printed circuit by the conductive joint; and
detector means carried by the support to detect an electrical interruption of a circuit under test including the conductive joint;
the device including storage means carried by the support for storing the successive times of interruptions.

23. The test device according to claim 22, in which the storage means comprise a non-volatile memory.

24. The test device according to claim 22, including means for measuring at least one environmental parameter associated with the support and storage means for storing at least one value of said environmental parameter.

25. The test device according to claim 24, in which the environmental parameter is selected from: a temperature; an acceleration to which the device is subjected; and a degree of humidity.

26. The test device according to claim 22, including a plurality of electrical component conductive terminations, each connected to the printed circuit via a conductive joint, the circuit under test having a run formed by the conductive joints interconnected in series.

27. The test device according to claim 26, in which the circuit under test includes a voltage divider bridge including resistive means connected in series with the run.

28. The test device according to claim 27, in which the resistive means comprise two two-terminal resistors connected in parallel.

29. The test device according to claim 27, in which the means for detecting an interruption comprise means for comparing a voltage output by the bridge with a predetermined threshold.

30. The test device according to claim 22, in which the detector means comprise logic analysis means provided with the least one input connected to the circuit under test and at least one output connected to the storage means.

31. The test device according to claim 30, in which the logic analysis means are provided with a plurality of inputs each connected to a corresponding circuit under test.

32. The test device according to claim 30, in which the logic analysis means are of the field programmable gate array type or of the microcontroller type.

33. The test device according to claim 30, in which each input of the logic analysis means is duplicated for redundancy purposes.

34. The test device according to claim 30, in which the storage means include a volatile memory of the logic analysis means.

35. The test device according to claim 22, including means carried by the support for determining a failure of the circuit under test, a failure corresponding to a predetermined number of successive interruptions occurring in a predetermined time interval.

36. The test device according to claim 30, in which the logic analysis means including means carried by the support for determining a failure of the circuit under test, a failure corresponding to a predetermined number of successive interruptions occurring in a predetermined time interval.

37. The test device according to claim 22, in which the conductive joint is formed by soldering, autogenous welding, contact under pressure, or forced engagement.

38. The test device according to claim 22, in which the support includes connection means for connection to an external device, in particular for connecting the storage means to the external device.

39. The test device according to claim 22, including means carried by the support for storing operating state parameters of the device in the event of an interruption in the electrical power supply to the device.

40. The test method for testing at least one conductive joint forming an electrical connection between an electrical component and a printed circuit, the method being of the type in which an electrical interruption is detected in a circuit under test including the conductive joint, wherein the interruption is detected by means of a device according to claim 22.

41. The test method according to claim 40, in which the interruption is detected by measuring a steady state parameter of the circuit under test while fed with DC.

42. The test method according to claim 40, in which the interruption is detected by measuring a transient state parameter of the circuit under test while fed in variable manner, preferably with pulses.
